(19) United States
(12) Patent Application Publication
(10) Pub. No.: US 2013/0209942 A1
(43) Pub. Date: Aug. 15, 2013

(54) PATTERN FORMATION METHOD

(71) Applicant: FUJIFILM Corporation, (US)

(72) Inventor: Tomokazu UMEZAWA, Minamiashigara-shi (JP)

(73) Assignee: FUJIFILM Corporation, Tokyo (JP)

(21) Appl. No.: 13/850,479

(22) Filed: Mar. 26, 2013

Related U.S. Application Data
(63) Continuation of application No. PCT/JP2011/005382, filed on Sep. 26, 2011.

(30) Foreign Application Priority Data
Sep. 29, 2010 (JP) 2010-218304

(51) Int. Cl. G03F 7/20

(52) U.S. Cl. CPC G03F 7/20
USPC 430/348

(57) ABSTRACT

A pattern is formed by forming, on a substrate, a resist layer made of oxonol-based dye, and by scanning the formed resist layer with a laser beam at a scan speed of higher than or equal to 1 m/s and lower than or equal to 30 m/s, and by developing the resist layer scanned with the laser beam using a developer containing alcohol as a main component.

### BACKGROUND OF THE INVENTION

1. Field of the Invention

The present invention relates to a pattern formation method for forming a pattern by thermal lithography.

2. Description of the Related Art

Conventionally, photolithography is known as a method for forming a pattern in an optical disk, a master disk for manufacturing optical disks, a light emitting device having a light emitting surface on which an uneven pattern is formed, and the like. The photolithography is a technique in which a photoresist layer is formed on a substrate, and the photoresist layer is exposed to light in a desirable pattern shape, and the photoresist layer is developed. Accordingly, a pattern composed of an exposed portion and an unexposed portion is formed.

Further, as a method that can form a higher resolution pattern than photolithography, thermal lithography is known (please refer to Japanese Unexamined Patent Publication No. 2007-216263 (Patent Document 1), Japanese Unexamined Patent Publication No. 2009-117019 (Patent Document 2), and International Patent Publication No. 2006/072859 (Patent Document 3)). This method is a technique in which a resist layer made of a thermally sublimatable or vaporizable material is formed on a substrate, and a desirable pattern is formed by heating and removing a portion of the resist layer that should form a depression by irradiating the portion with a condensed laser beam.

### SUMMARY OF THE INVENTION

In any thermal lithography proposed in Patent Documents 1 through 3, a pattern is formed by positive-type processing, in which a depression is formed by a portion heated with a laser beam. However, some pattern requires negative-type processing, in which a projection is formed by a portion heated with a laser beam, to improve the efficiency of formation of the pattern. However, currently, there is no technique that can realize negative-type processing by thermal lithography.

In view of the foregoing circumstances, it is an object of the present invention to provide a pattern formation method that can realize negative-type processing by thermal lithography.

A pattern formation method of the present invention is a pattern formation method for forming a pattern by thermal lithography, the method comprising the steps of:

forming, on a substrate, a resist layer made of oxonol-based dye;

scanning the formed resist layer with a laser beam at a scan speed of higher than or equal to 1 m/s and lower than or equal to 30 m/s; and

developing the resist layer scanned with the laser beam using a developer containing alcohol as a main component.

Here, the term “main component” is defined as a component the content of which is 50 mol % or higher. Further, the developer may be diluted with a solvent, such as water.

In the aforementioned method, the scan speed may be higher than or equal to 3.8 m/s and lower than or equal to 28 m/s.

Further, the alcohol may be methanol or ethanol.

In the pattern formation method of the present invention, first, a resist layer made of oxonol-based dye is formed on a substrate, and the formed resist layer is scanned with a laser beam at a scan speed of higher than or equal to 1 m/s and lower than or equal to 30 m/s. Consequently, a portion of the resist layer heated by scan with the laser beam is converted to a material having low solubility with respect to alcohol. Next, the resist layer scanned with the laser beam is developed using a developer containing alcohol as a main component. Consequently, a portion other than the portion heated with the laser beam is removed, and a pattern in which the portion heated with the laser beam forms a projection is formed.

As described above, according to the pattern formation method of the present invention, it is possible to realize negative-type processing by thermal lithography.

### BRIEF DESCRIPTION OF THE DRAWINGS

FIG. 1 is a flow chart illustrating a pattern formation method of the present invention;

FIG. 2 is a diagram illustrating the processing state of a pattern formed in Example 1;

FIG. 3 is a diagram illustrating the processing state of a pattern formed in Example 2; and

FIG. 4 is a diagram illustrating the processing state of a pattern formed in Example 6.

### DESCRIPTION OF THE PREFERRED EMBODIMENTS

Hereinafter, embodiments of the present invention will be described with reference to drawings. A pattern formation method of the present invention forms a pattern by thermal lithography, and includes a resist layer formation step, a laser beam scan step, and a development step. The resist layer formation step forms a resist layer on a substrate. The laser beam scan step scans the formed resist layer with a laser beam. The development step develops the resist layer that has been scanned with the laser beam using a developer. Next, each step will be described in detail.

[Resist Layer Formation Step]

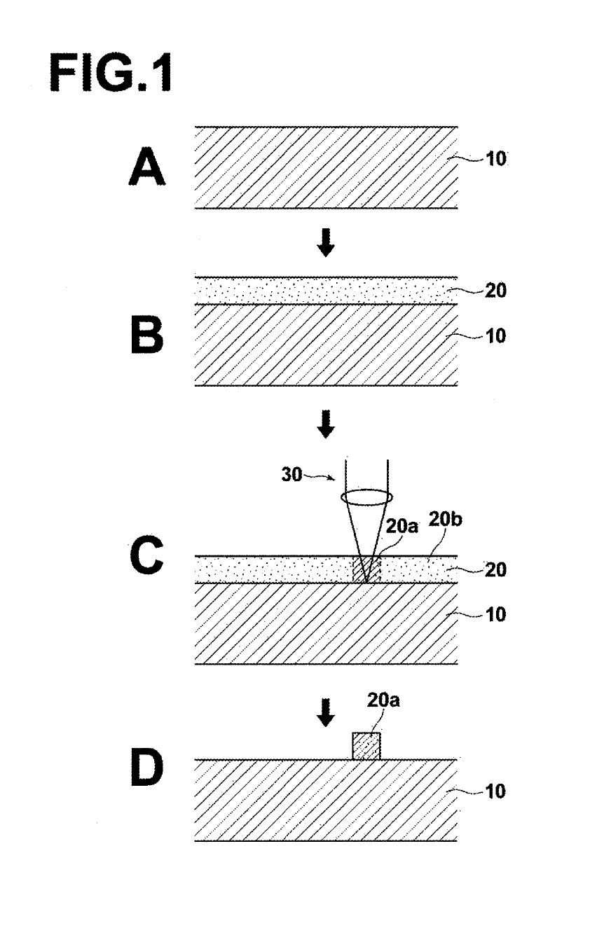

First, as illustrated in Sections A and B of FIG. 1, a flat substrate 10 is prepared, and a resist layer 20 made of oxonol-based dye is formed on the substrate 10.

The resist layer 20 is formed by preparing a coating solution in which oxonol dye is dissolved in solvent, and by forming a coating by applying the prepared coating solution onto the surface of the substrate 10. After then, the formed coating is dried to form the resist layer 20.

As the oxonol dye, a dye disclosed, for example, in Japanese Unexamined Patent Publication No. 2006-212790 may be used. One of examples of the desirable structure of oxonol dye is represented by the following general formula (1):

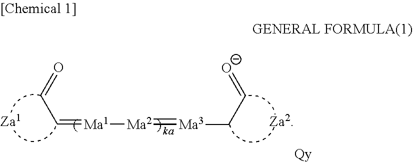

In the general formula (1), each of Za¹ and Za² independently represents a group of atoms forming an acidic nucleus. Further, each of Ma¹, Ma² and Ma¹ independently represents a substituted or unsubstituted methine group, and ka represents an integer of from 0 to 3. Plural Ma¹, Ma², which are present when ka is 2 or greater, may be the same, or different. Further, Q represents an ion that neutralizes a charge, and y represents the number of ions necessary to neutralize the charge.

Further, one of examples of desirable structure of oxonol dye is represented by the following general formula (2):

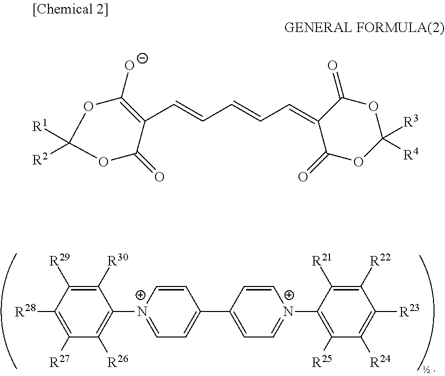

In the general formula (2), each of R¹, R², R³ and R⁴ independently represents a substituted or unsubstituted alkyl group, or a substituted or unsubstituted aryl group, or a substituted or unsubstituted heterocyclic group. Further, each of R²¹, R²², R²³, R²⁴, R²⁵, R²⁶, R²⁷, R²⁸, R²⁹, and R³⁰ independently represents a hydrogen atom, or a substituent.

Alternatively, oxonol-based dyes A and B, which will be described next, may be used as the oxonol dye. As the oxonol dye A, a compound represented by the following general formula (3) is desirable:

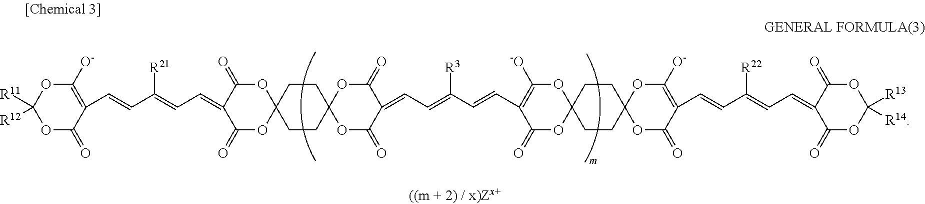

In the general formula (3), each of R¹¹, R¹², Rⁿ and R¹⁴ independently represents a hydrogen atom, or a substituted or unsubstituted alkyl group, or a substituted or unsubstituted aryl group, or a substituted or unsubstituted heterocyclic group. Further, R²¹, R²² and R³ represent a hydrogen atom, or a substituted or unsubstituted alkyl group, or a substituted or unsubstituted alkoxy group, or a substituted or unsubstituted aryl group, or a substituted or unsubstituted aryloxy group, or a substituted or unsubstituted heterocyclic group, or a halogen atom, or a carboxy group, or a substituted or unsubstituted alkoxycarbonyl group, or a cyano group, or a substituted or unsubstituted acyl group, or a substituted or unsubstituted carbamoyl group, or an amino group, or a substituted amino group, or a sulfo group, or a hydroxy group, or a nitro group, or a substituted or unsubstituted alkylsulfonylamino group, or a substituted or unsubstituted arylsulfonylamino group, or a substituted or unsubstituted carbamoylamino group, or a substituted or unsubstituted alkyl sulfonyl group, or a substituted or unsubstituted arylsulfonyl group, or a substituted or unsubstituted alkylsulfinyl group, or a substituted or unsubstituted arylsulfinyl group, or a substituted or unsubstituted sulfamoyl group, and m represents an integer greater than or equal to 0. Plural R³, which are present when m is 2 or greater, may be the same, or different. Further, Z^{x+} represents a cation, and x is an integer greater than or equal to 1.

As oxonol dye B, a compound represented by the following general formula (4) is desirable:

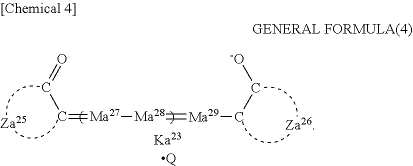

In the general formula (4), each of Za²⁵ and Za²⁶ independently represents a group of atoms forming an acidic nucleus. Further, each of Ma²⁷ Ma²⁸ and Ma²⁹ independently represents a substituted or unsubstituted methine group, and Ka²³ represents an integer of from 0 to 3. Further, Q represents a cation that neutralizes a charge.

As solvent for the coating solution, esters, such as butyl acetate, ethyl lactate and cellosolve acetate; ketones, such as methyl ethyl ketone, cyclohexanone and methyl isobutylketone; chlorinated hydrocarbons, such as dichloromethane, 1,2-dichloroethane and chloroform; amides, such as dimethylformamide; hydrocarbons, such as cyclohexane; ethers, such as tetrahydrofuran, ethyl ether and dioxane; alcohols, such as ethanol, n-propanol, isopropanol, n-butanol and diacetone alcohol; fluorine-based solvents, such as 2,2,3,3-tetrafluoropropanol; and glycol ethers, such as ethylene glycol monomethyl ether, ethylene glycol monoethyl ether and propylene glycolmonomethyl ether, may be used.

The coating method is, for example, a spray method, a spin coating method, a dip method, a roll coating method, a blade coating method, a doctor roll method, a screen printing method, or the like.

It is desirable that the optical density (OD value) of the resist layer 20 with respect to light having the wavelength of 580 nm is in the range of from 0.4 to 1.0. Here, the OD value represents, by a logarithm, the degree of absorption of light when the light passes through the resist layer 20. If the OD value is too low or too high, it is impossible to stably form high resolution patterns.

[Laser Beam Scan Step]

Next, as illustrated in Section C of FIG. 1, the resist layer 20 is scanned with a laser beam condensed by a lens in an optical system 30. The entire area of the disk-shaped substrate 10 is scanned with the laser beam, for example, by moving the optical system 30 in the direction of the radius of the substrate 10 while the substrate 10 is rotated.

In this case, the behavior of either one or both of the substrate 10 and the optical system 30 is controlled so that the relative scan speed of the laser beam that scans the resist layer 20 is higher than or equal to 1 m/s and less than or equal to 30 m/s. If the scan speed is too high, a portion irradiated with the laser beam is sublimated or vaporized, and forms a depression. If the scan speed is too low, there is a problem that processing time becomes long. Further, since control of recording power becomes difficult, it is difficult to obtain a stable shape. Further, it is more desirable that the scan speed is higher than or equal to 3.8 m/s and less than or equal to 28 m/s.

Power Y of the laser beam is set so as to satisfy the condition of the following formula (1) when the scan speed of the laser beam is X. If the power is too low, the physical properties of the portion irradiated with the laser beam do not change (change in the solubility with respect to alcohol). Therefore, no pattern is formed. If the power is too high, the physical properties of a portion in the vicinity of the portion irradiated with the laser beam also change, and it is impossible to form high resolution patterns:

$$\begin{matrix}[ Formula 1 ] & \\ \{ \begin{matrix}Y > - 0.0012 {X}^{2} + 0.6374 X + 5.1504 \\ Y < - 0.0019 {X}^{2} + 1.0623 X + 8.584 .\end{matrix} & ( 1 )\end{matrix}$$

It is more desirable to set the power Y of the laser beam so as to further satisfy the condition of the following formula (2). It is still more desirable to set the power Y of the laser beam so as to further satisfy the condition of the following formula (3). When the power Y of the laser beam satisfies the condition of the formula (2), it is possible to more stably form high-resolution patterns. When the power Y of the laser beam satisfies the condition of the formula (3), it is possible to form high-resolution patterns in most excellent shape:

$$\begin{matrix}[ Formula 2 ] & \\ \{ \begin{matrix}Y > - 0.0012 {X}^{2} + 0.6978 X + 5.4938 \\ Y < - 0.0018 {X}^{2} + 1.0198 X + 8.2407 ;\end{matrix} \\ and & ( 2 ) \\ [ Formula 3 ] & \\ Y = - 0.0015 {X}^{2} + 0.8498 X + 6.8672 . & ( 3 )\end{matrix}$$

Further, it is desirable to set the power Y of the laser beam so as to satisfy the condition of the following formula (4) with respect to OD value T of the resist layer 20 especially when the scan speed of the laser beam is 9.2 m/s. Examples of setting of power Y with respect to OD value T are shown in the following Table (1):

[Formula 4]

Y=74.491T²−113.8T+57.135 (4).

TABLE 1

| OD VALUE | POWER[mW] |
|---|---|
| 0.40 | 23.5 |
| 0.45 | 21.0 |
| 0.50 | 18.9 |
| 0.55 | 17.1 |
| 0.60 | 15.7 |
| 0.65 | 14.6 |
| 0.70 | 14.0 |
| 0.75 | 13.7 |
| 0.80 | 13.8 |
| 0.85 | 14.2 |
| 0.90 | 15.1 |
| 0.95 | 16.3 |
| 1.00 | 17.8 |

[Development Step]

Finally, as illustrated in Section D of FIG. 1, the resist layer that has been scanned with the laser beam is developed with a developer containing alcohol as a main component thereof. Then, the portion 20a that has been irradiated with the laser beam is not dissolved in the developer, and only a portion 20b that has not been irradiated with the laser beam is removed by being dissolved in the developer. Consequently, a pattern in which the portion 20a irradiated with the laser beam forms a projection is formed.

Here, examples of alcohol are methanol (methyl alcohol), ethanol (ethyl alcohol), and the like. A development method is, for example, a method in which the substrate on which the resist layer was deposited, and which has been scanned with the laser beam, is immersed for a predetermined period in a developer kept in a development bath. When the developer is alcohol, it is desirable that the immersion time is in the range of from 1 to 20 minutes. If the immersion time is too short, a part of the portion 20b that has not been irradiated with the laser beam is not fully dissolved, and remains. If the immersion time is too long, a part of the portion 20a that has been irradiated with the laser beam is dissolved.

The following Table 2 shows a result of evaluation of patterns formed by using the pattern formation method of the present invention. The OD value of the resist layer 20 was set to 0.65, and the patterns were formed by changing the power of the laser beam to 6.5, 7.0, 7.5, . . . , 40 (mW) while the scan speed of the laser beam was fixed at each of 3.8, 9.2, 15.4, 23.0, 28.0, and 30.1 (m/s). In Table 2, patterns are evaluated in the following manner. When a projection shape smaller than or equal to the spot diameter of the optical system 30 is recognized in the resist layer portion scanned with the laser beam, the evaluation is o. Even if the projection shapes are recognized, if the shapes are not uniform, the evaluation is Δ. When neither a projection shape nor a depression shape is recognized, the evaluation is x (a). When a projection shape larger than or equal to the spot diameter of the optical system 30 is recognized, the evaluation is x (b). When a depression shape is recognized without development using methanol, the evaluation is x (c).

TABLE 2

| | | LASER POWER [mW] | | | | | | | | | | | | | | | | |
|---|---|---|---|---|---|---|---|---|---|---|---|---|---|---|---|---|---|---|
| | | 6.5 | 7 | 7.5 | 8 | 8.5 | 9 | 9.5 | 10 | 10.5 | 11 | 11.5 | 12 | 12.5 | 13 | 13.5 | 14 | 14.5 |
| SCAN | 3.8 | x(a) | x(a) | Δ | Δ | ◯ | ◯ | ◯ | ◯ | ◯ | ◯ | ◯ | ◯ | Δ | x(b) | x(b) | x(b) | x(b) |
| SPEED | 9.2 | x(a) | x(a) | x(a) | x(a) | x(a) | x(a) | x(a) | x(a) | Δ | Δ | ◯ | ◯ | ◯ | ◯ | ◯ | ◯ | ◯ |
| [m/s] | 15.4 | x(a) | x(a) | x(a) | x(a) | x(a) | x(a) | x(a) | x(a) | x(a) | x(a) | x(a) | x(a) | x(a) | x(a) | x(a) | x(a) | Δ |
| | 23.0 | x(a) | x(a) | x(a) | x(a) | x(a) | x(a) | x(a) | x(a) | x(a) | x(a) | x(a) | x(a) | x(a) | x(a) | x(a) | x(a) | x(a) |
| | 28.0 | x(a) | x(a) | x(a) | x(a) | x(a) | x(a) | x(a) | x(a) | x(a) | x(a) | x(a) | x(a) | x(a) | x(a) | x(a) | x(a) | x(a) |
| | 30.1 | x(a) | x(a) | x(a) | x(a) | x(a) | x(a) | x(a) | x(a) | x(a) | x(a) | x(a) | x(a) | x(a) | x(a) | x(a) | x(a) | x(a) |
| | | LASER POWER [mW] | | | | | | | | | | | | | | | | |
| | | 15 | 15.5 | 16 | 16.5 | 17 | 17.5 | 18 | 18.5 | 19 | 19.5 | 20 | 20.5 | 21 | 21.5 | 22 | 22.5 | 23 |
| SCAN | 3.8 | x(b) | x(b) | x(b) | x(b) | x(b) | x(b) | x(b) | x(b) | x(b) | x(b) | x(b) | x(b) | x(b) | x(b) | x(b) | x(b) | x(b) |
| SPEED | 9.2 | ◯ | ◯ | ◯ | ◯ | ◯ | ◯ | Δ | x(b) | x(b) | x(b) | x(b) | x(b) | x(b) | x(b) | x(b) | x(b) | x(b) |
| [m/s] | 15.4 | Δ | ◯ | ◯ | ◯ | ◯ | ◯ | ◯ | ◯ | ◯ | ◯ | ◯ | ◯ | ◯ | ◯ | ◯ | ◯ | ◯ |
| | 23.0 | x(a) | x(a) | x(a) | x(a) | x(a) | x(a) | x(a) | x(a) | x(a) | Δ | ◯ | ◯ | ◯ | ◯ | ◯ | ◯ | ◯ |
| | 28.0 | x(a) | x(a) | x(a) | x(a) | x(a) | x(a) | x(a) | x(a) | x(a) | x(a) | x(a) | x(a) | x(a) | x(a) | x(a) | Δ | Δ |
| | 30.1 | x(a) | x(a) | x(a) | x(a) | x(a) | x(a) | x(a) | x(a) | x(a) | x(a) | x(a) | x(a) | x(a) | x(a) | x(a) | x(a) | x(a) |
| | | LASER POWER [mW] | | | | | | | | | | | | | | | | |
| | | 23.5 | 24 | 24.5 | 25 | 25.5 | 26 | 26.5 | 27 | 27.5 | 28 | 28.5 | 29 | 29.5 | 30 | 30.5 | 31 | 31.5 |
| SCAN | 3.8 | x(b) | x(b) | x(b) | x(b) | x(b) | x(b) | x(b) | x(b) | x(b) | x(b) | x(b) | x(b) | x(b) | x(b) | x(b) | x(b) | x(b) |
| SPEED | 9.2 | x(b) | x(b) | x(b) | x(b) | x(b) | x(b) | x(b) | x(b) | x(b) | x(b) | x(b) | x(b) | x(b) | x(b) | x(b) | x(b) | x(b) |
| [m/s] | 15.4 | ◯ | Δ | Δ | x(b) | x(b) | x(b) | x(b) | x(b) | x(b) | x(b) | x(b) | x(b) | x(b) | x(b) | x(b) | x(b) | x(b) |
| | 23.0 | ◯ | ◯ | ◯ | ◯ | ◯ | ◯ | ◯ | ◯ | ◯ | ◯ | ◯ | ◯ | ◯ | ◯ | ◯ | Δ | Δ |
| | 28.0 | Δ | ◯ | ◯ | ◯ | ◯ | ◯ | ◯ | ◯ | ◯ | ◯ | ◯ | ◯ | ◯ | ◯ | ◯ | ◯ | ◯ |
| | 30.1 | x(c) | x(c) | x(c) | x(c) | x(c) | x(c) | x(c) | x(c) | x(c) | x(c) | x(c) | x(c) | x(c) | x(c) | x(c) | x(c) | x(c) |
| | | LASER POWER [mW] | | | | | | | | | | | | | | | | |
| | | 32 | 32.5 | 33 | 33.5 | 34 | 34.5 | 35 | 35.5 | 36 | 36.5 | 37 | 37.5 | 38 | 38.5 | 39 | 39.5 | 40 |
| SCAN | 3.8 | x(b) | x(b) | x(b) | x(b) | x(b) | x(b) | x(b) | x(b) | x(b) | x(b) | x(b) | x(b) | x(b) | x(b) | x(b) | x(b) | x(b) |
| SPEED | 9.2 | x(b) | x(b) | x(b) | x(b) | x(b) | x(b) | x(b) | x(b) | x(b) | x(b) | x(b) | x(b) | x(b) | x(b) | x(b) | x(b) | x(b) |
| [m/s] | 15.4 | x(b) | x(b) | x(b) | x(b) | x(b) | x(b) | x(b) | x(b) | x(b) | x(b) | x(b) | x(b) | x(b) | x(b) | x(b) | x(b) | x(b) |
| | 23.0 | Δ | x(b) | x(b) | x(b) | x(b) | x(b) | x(b) | x(b) | x(b) | x(b) | x(b) | x(b) | x(b) | x(b) | x(b) | x(b) | x(b) |
| | 28.0 | ◯ | ◯ | ◯ | ◯ | ◯ | ◯ | ◯ | Δ | Δ | Δ | x(b) | x(b) | x(b) | x(b) | x(b) | x(b) | x(b) |
| | 30.1 | x(c) | x(c) | x(c) | x(c) | x(c) | x(c) | x(c) | x(c) | x(c) | x(c) | x(c) | x(c) | x(c) | x(c) | x(c) | x(c) | x(c) |

According to Table 2, when the scan speed of the laser beam is 30.1 m/s, no projection shape is formed in the portion of the resist layer scanned with the laser beam in all the range of the power of the laser beam. However, when the scan speed of the laser beam is 3.8 m/s, if the power of the laser beam is in the range of 8.5 to 12 mW, it is possible to recognize formation of a projection shape smaller than or equal to the spot diameter of the optical system 30 in the portion of the resist layer that has been scanned with the laser beam. When the scan speed of the laser beam is 9.2 m/s, if the power of the laser beam is in the range of 11.5 to 17.5 mW, it is possible to recognize formation of a projection shape smaller than or equal to the spot diameter of the optical system 30 in the portion of the resist layer. When the scan speed of the laser beam is 15.4 m/s, if the power of the laser beam is in the range of 15.5 to 23.5 mW, it is possible to recognize formation of a projection shape smaller than or equal to the spot diameter of the optical system 30 in the portion of the resist layer. When the scan speed of the laser beam is 23.0 m/s, if the power of the laser beam is in the range of 20 to 30.5 mW, it is possible to recognize formation of a projection shape smaller than or equal to the spot diameter of the optical system 30 in the portion of the resist layer. When the scan speed of the laser beam is 28.0 m/s, if the power of the laser beam is in the range of 24 to 35 mW, it is possible to recognize formation of a projection shape smaller than or equal to the spot diameter of the optical system 30 in the portion of the resist layer.

As described above, it is possible to realize negative-type processing of a high resolution pattern smaller than or equal to the spot diameter of the optical system 30 by thermal lithography at least when scan speed X of the laser beam is higher than or equal to 3.8 m/s and lower than equal to 28 m/s, and power Y of the laser beam satisfies the condition of the aforementioned formula (2).

In the aforementioned embodiments, a case in which the resist layer is made of oxonol dye was described. However, even if the resist layer is made of a material other than the oxonol dye, it is considered that there is a possibility that negative-type processing is performable if the condition of scan with the laser beam is appropriately adjusted. Here, examples of the other material are methine dye (cyanine dye, hemicyanine dye, styryl dye, oxonol dye, merocyanine dye, and the like), macrocyclic dye (phthalocyanine dye, naphthalocyanine dye, porphyrin dye, and the like), azo dye (including azo metal chelate dye), arylidene dye, complex dye, coumarin dye, azole derivative, triazine derivative, 1-aminobutadiene derivative, cinnamic acid derivative, quinophthalone-based dye, and the like.

Next, examples in which the effects of the present invention have been recognized will be described.

### EXAMPLE 1

### Formation of Resist Layer

A resist layer was formed by applying a coating solution on a substrate made of silicon (Si) by spin coating, and the coating solution having been obtained by dissolving 1.00 g of “oxonol dye A”, which is represented by the following chemical formula, in 100 ml of 2,2,3,3-tetrafluoropropanol. At this time, the resist layer was fanned in such a manner that the optical density (OD value) with respect to light having the wavelength of 580 nm is 0.65. Accordingly, a resist structure composed of the substrate and the resist layer formed on the substrate was formed.

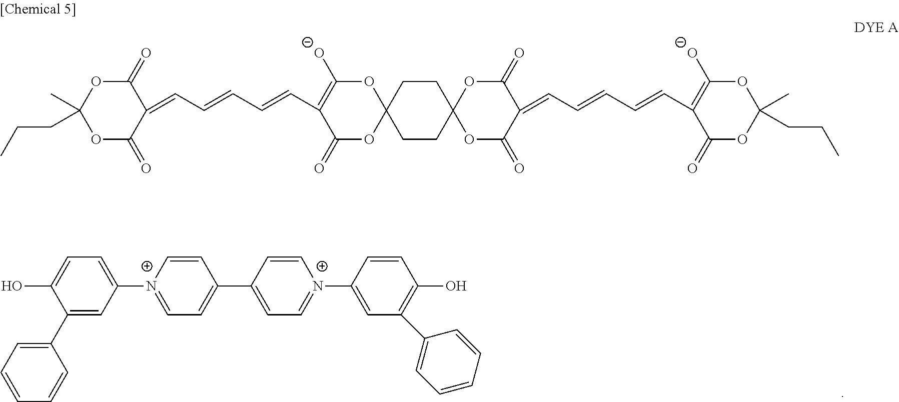 [SMILES: CCCC1(C)OC(=O)C(=C/C=C/C=C/C2=C([O-])OC3(CCC4(CC3)OC(=O)C(=C/C=C/C=C/C3=C([O-])OC(C)(CCC)OC3=O)C(=O)O4)OC2=O)C(=O)O1 ; Oc1ccc(-[n+]2ccc(-c3cc[n+](-c4ccc(O)c(-c5ccccc5)c4)cc3)cc2)cc1-c1ccccc1]

Scan with Laser Beam

The resist layer, which had been formed as described above, was scanned with a laser beam by using a laser exposure apparatus (laser wavelength A: 660 nm, numerical aperture of object lens NA: 0.60, and spot diameter D of laser beam: 0.66 um (=0.6 λ/NA)) under the following conditions:

Scan Speed 9.2 m/s;

Power 16 mW; and

Laser Pulse 10.43 MHz (Duty ratio 26%).

### Development

The substrate on which the resist layer had been deposited, and which had been scanned with the laser beam, was immersed in methanol for 10 minutes.

### Evaluation

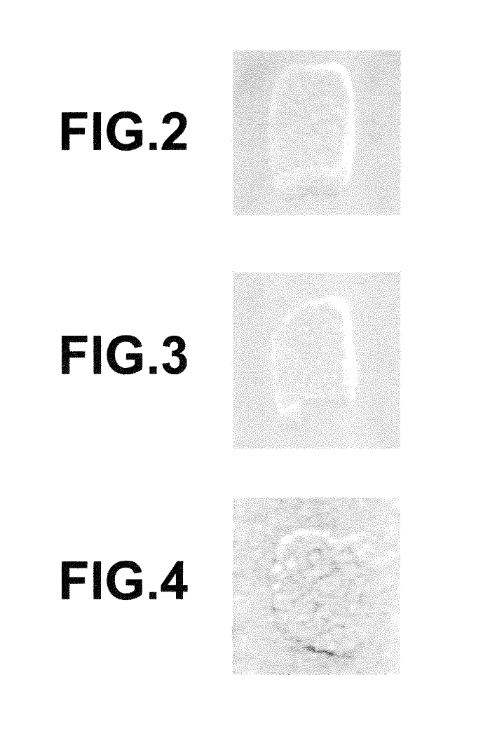

The surface of the substrate after development, to which the resist layer adhered, was observed by a scan-type electronic microscope (SEM). In consequence, the resist remained only in a portion that had been scanned with the laser beam, and formation of a projection structure, as illustrated in FIG. 2, was recognized. The length of the projection structure in the direction of laser scan was 0.46 um, and the length of the projection structure in a direction orthogonal to the direction of the laser scan was 0.31 um.

### EXAMPLE 2

Except for scanning with a laser beam under the following condition, processing and evaluation were performed under the same condition as Example 1:

Scan Speed 15.4 m/s;

Power 19 mW; and

Laser Pulse 17.47 MHz (Duty ratio 33%).

### Evaluation

In consequence, the resist remained only in a portion that had been scanned with the laser beam, and formation of a projection structure, as illustrated in FIG. 3, was recognized. The length of the projection structure in the direction of laser scan was 0.44 um, and the length of the projection structure in a direction orthogonal to the direction of the laser scan was 0.31 um.

### EXAMPLE 3

Except for forming the resist layer in such a manner that the OD value of the resist layer is 0.50, and scanning with a laser beam at the power of 19 mW, processing and evaluation were performed under the same condition as Example 1.

### Evaluation

In consequence, the resist remained only in a portion that had been scanned with the laser beam, and formation of a projection structure was recognized. The length of the projection structure in the direction of laser scan was 0.45 um, and the length of the projection structure in a direction orthogonal to the direction of the laser scan was 0.31 um.

### EXAMPLE 4

Except for forming the resist layer in such a manner that the OD value of the resist layer is 0.40, and scanning with a laser beam at the power of 23 mW, processing and evaluation were performed under the same condition as Example 1.

### Evaluation

In consequence, the resist remained only in a portion that had been scanned with the laser beam, and formation of a projection structure was recognized. The length of the projection structure in the direction of laser scan was 0.43 um, and the length of the projection structure in a direction orthogonal to the direction of the laser scan was 0.32 um.

### EXAMPLE 5

Except for forming the resist layer in such a manner that the OD value of the resist layer is 0.75, and scanning with a laser beam at the power of 14 mW, processing and evaluation were performed under the same condition as Example 1.

### Evaluation

In consequence, the resist remained only in a portion that had been scanned with the laser beam, and formation of a projection structure was recognized. The length of the projection structure in the direction of laser scan was 0.43 um, and the length of the projection structure in a direction orthogonal to the direction of the laser scan was 0.30 um.

### EXAMPLE 6

Except for forming the resist layer in such a manner that the OD value of the resist layer is 0.95, and scanning with a laser beam at the power of 25 mW, processing and evaluation were performed under the same condition as Example 2.

### Evaluation

In consequence, the resist remained only in a portion that had been scanned with the laser beam, and formation of a projection structure, as illustrated in FIG. 4, was recognized. The length of the projection structure in the direction of laser scan was 0.44 um, and the length of the projection structure in a direction orthogonal to the direction of the laser scan was 0.41 um.

### EXAMPLE 7

Except for developing the substrate, to which the resist layer scanned with a laser beam adhered, after immersing the substrate in ethanol for one minute, processing and evaluation were performed under the same condition as Example 6.

### Evaluation

In consequence, the resist remained only in a portion that had been scanned with the laser beam, and formation of a projection structure was recognized. The length of the projection structure in the direction of laser scan was 0.38 um, and the length of the projection structure in a direction orthogonal to the direction of the laser scan was 0.36 um.

What is claimed is:

1. A pattern formation method for forming a pattern by thermal lithography, the method comprising the steps of:
forming, on a substrate, a resist layer made of oxonol-based dye;
scanning the formed resist layer with a laser beam at a scan speed of higher than or equal to 1 m/s and lower than or equal to 30 m/s; and
developing the resist layer scanned with the laser beam using a developer containing alcohol as a main component.

2. A pattern formation method, as defined in claim 1, wherein the scan speed is higher than or equal to 3.8 m/s and lower than or equal to 28 m/s.

3. A pattern formation method, as defined in claim 1, wherein the alcohol is methanol or ethanol.

4. A pattern formation method, as defined in claim 2, wherein the alcohol is methanol or ethanol.
